(19) United States
(12) Patent Application Publication
(10) Pub. No.: US 2013/0163186 A1
(43) Pub. Date: Jun. 27, 2013

(54) CONNECTION UNIT AND ELECTRONIC APPARATUS

(71) Applicant: Sony Corporation, Tokyo (JP)

(72) Inventor: Shigeru Mizusawa, Tokyo (JP)

(73) Assignee: Sony Corporation, Tokyo (JP)

(21) Appl. No.: 13/693,261

(22) Filed: Dec. 4, 2012

(30) Foreign Application Priority Data
Dec. 21, 2011 (JP) 2011-279503

(51) Int. Cl. H05K 7/14

(52) U.S. Cl. CPC H05K 7/14
USPC 361/679.41

(57) ABSTRACT

Disclosed herein is a connection unit, including: a connector unit having a connection connector to which a connector portion of a personal digital assistance is connected; an apparatus insertion opening into which the personal digital assistance is inserted; a cover which is pivoted between a closing position where the apparatus insertion opening is closed and an opening position where the apparatus insertion opening is opened, and which receives and holds the personal digital assistance connected to the connection connector in a state in which at least a part of the apparatus insertion opening is opened; and an adjusting mechanism having a manipulation portion, and adjusting a pivot position of the cover by a manipulation carried out for the manipulation portion.

### BACKGROUND

The present disclosure relates to a connection unit and an electronic apparatus. More particularly, the present disclosure relates to a connection unit in which a pivot position of a cover for opening and closing an apparatus insertion opening can be adjusted by an adjusting mechanism, thereby protecting a connector without rocketing a manufacturing cost, and an electronic apparatus including the same.

There are known electronic apparatuses such as a speaker, stereo equipment, and a charging apparatus to each of which a personal digital assistance such as a digital music player (DMP) or a mobile phone is adapted to be mounted.

Each of these electronic apparatuses is provided with a connection unit having a connection connector to which a connector portion of the personal digital assistance is connected. This technique, for example, is described in Japanese Patent Laid-Open No. 2004-135119. The personal digital assistance is connected to the connection connector of the connection unit, whereby, for example, a sound or an image based on an audio signal or a video signal recorded in the personal digital assistance is outputted.

In some of the electronic apparatuses as described above, in a phase of connecting the connector portion in the personal digital assistance to the connection connector in the electronic apparatus, a circular attachment is mounted to an insertion portion, of the connection unit, into which the personal digital assistance is adapted to be inserted. An insertion hole of the attachment is formed so as to have a size and a shape corresponding to a size and a shape of the personal digital assistance adapted to be inserted thereinto. Thus, the personal digital assistance is inserted into the insertion hole of the attachment, so that the connector portion is connected to the connection connector.

The personal digital assistance is inserted into the insertion hole of the attachment in such a manner, and the connector portion thereof is in turn connected to the connection connector to be mounted to the connection unit. Therefore, when a manipulation is carried out for a manipulation surface provided on a front surface of the personal digital assistance, and so forth in a state in which the personal digital assistance is mounted to the connection unit, since the personal digital assistance is held by the attachment, a displacement of the personal digital assistance in a depressing manipulation direction is controlled by the attachment, so that a load is hardly generated in the connection connector. As a result, the connector portion and the connection connector is prevented from being broken.

### SUMMARY

However, in the connection unit to which the attachment described above is mounted to hold the personal digital assistance, it is necessary to prepare the attachment corresponding to the shape and size of the personal digital assistance adapted to be mounted thereto. Thus, plural attachments need to be prepared so as to correspond to the kinds and sizes of the personal digital assistances adapted to be mounted to the plural attachments, which results in that the manufacturing cost is rocketed.

In addition, in a state in which the personal digital assistance is detached from the connection unit, since the connection connector is exposed, it is also feared that the grit and dust are adhered to the connection connector. As a result, there is also caused a problem that the protection of the connection connector becomes insufficient.

The present disclosure has been made in order to solve the problems described above, and it is therefore desirable to provide a connection unit with which a connection connector can be protected without rocketing a manufacturing cost, and an electronic apparatus including the same.

In order to attain the desire, firstly, according to an embodiment of the present disclosure, there is provided a connection unit including: a connector unit having a connection connector to which a connector portion of a personal digital assistance is connected; an apparatus insertion opening into which the personal digital assistance is inserted; a cover which is pivoted between a closing position where the apparatus insertion opening is closed and an opening position where the apparatus insertion opening is opened, and which receives and holds the personal digital assistance connected to the connection connector in a state in which at least a part of the apparatus insertion opening is opened; and an adjusting mechanism having a manipulation portion, and adjusting a pivot position of the cover by a manipulation carried out for the manipulation portion.

Therefore, in the connection unit described above, the cover can be pivoted between the closing position where the apparatus insertion opening is closed and the opening position where the apparatus insertion opening is opened. Also, the pivot position of the cover is adjusted by the adjusting mechanism.

Secondly, preferably, the connection unit may be provided with a biasing spring biasing the cover toward the closing position when the cover is pivoted from an intermediate pivot position between the closing position and the opening position to the closing position side with the intermediate pivot position as a reference, and biasing the cover toward the opening position when the cover is pivoted from the intermediate pivot position to the opening position side.

By providing the biasing spring for biasing the cover toward the closing position when the cover is pivoted from the intermediate pivot position to the closing position side, and biasing the cover toward the opening position when the cover is pivoted from the intermediate pivot position to the opening position side, the pivot of the cover is prevented from being stopped between the closing position and the opening position.

Thirdly, preferably, in the connection unit described above, the adjusting mechanism may be provided with a slider against which the cover is pressed by the biasing spring between the intermediate pivot position and the opening position, and the cover may be pivoted between the intermediate pivot position and the opening position by a movement of the slider.

The adjusting mechanism is provided with the slider against which the cover is pressed by the biasing spring between the intermediate pivot position and the opening position, and the cover is pivoted between the intermediate pivot position and the opening position by the movement of the slider, whereby with respect to the pivot position of the cover, the adjustment in and after the second time is not required.

Fourthly, preferably, in the connection unit described above, the adjusting mechanism may be provided with a feed screw moving the slider.

The adjusting mechanism is provided with the feed screw for moving the slider, whereby the adjustment for the pivot position of the cover is determined depending on a rotational direction and a rotation amount of the feed screw.

Fifthly, preferably, in the connection unit described above, a rotating dial may be used as a manipulation portion of the adjusting mechanism.

The rotating dial is used as the manipulation portion of the adjusting mechanism, whereby the adjustment for the pivot position of the cover is determined depending on the rotational direction and the rotation amount of the rotating dial.

Sixthly, preferably, in the connection unit described above, the apparatus insertion opening may be formed in a chassis, and the cover may be inserted into an inside of the chassis as the cover is pivoted from the closing position toward the opening position.

The apparatus insertion opening may be formed in the chassis, and the cover is inserted into the inside of the chassis as the cover is pivoted from the closing position toward the opening position, whereby the cover does not interfere with the personal digital assistance in a phase of mounting the personal digital assistance to the connection unit.

Seventhly, preferably, in the connection unit described above, a cushion may be stuck to a portion of the cover which contacts the personal digital assistance.

The cushion is stuck to the portion of the cover which contacts the personal digital assistance, whereby the cushion contacts the personal digital assistance, so that the personal digital assistance is held by the cover.

Eighthly, preferably, in the connection unit described above, the connection unit may be provided with a supporting portion supporting the connector unit, and the connector unit may be pivoted for the supporting portion in the same direction as the pivot direction of the cover.

The connection unit is provided with the supporting portion for supporting the connector unit, and the connector unit can be pivoted for the supporting portion in the same direction as the pivot direction of the cover, whereby a load applied to both of the connector portion of the personal digital assistance, and the connection connector of the connection unit when the personal digital assistance is moved is suppressed irrespective of the pivoting operation of the cover.

Ninthly, preferably, in the connection unit described above, the connector unit may be made pivotable with a predetermined reference position as a reference, in which the connection unit may be further provided with a returning spring biasing the connector unit toward the reference portion.

The connector unit is made pivotable with the predetermined reference position as the reference, and the connection unit is further provided with the returning spring for biasing the connector unit toward the reference portion, whereby when a force applied to the personal digital assistance is released, the connector unit is returned together with the personal digital assistance back to the reference position by a biasing force of the returning spring.

According to another embodiment of the present disclosure, tenthly, there is provided an electronic apparatus including: a connection unit to which a personal digital assistance is mounted, in which the connection unit includes: a connector unit having a connection connector to which a connector portion of a personal digital assistance is connected; an apparatus insertion opening into which said personal digital assistance is inserted; a cover which is pivoted between a closing position where the apparatus insertion opening is closed and an opening position where the apparatus insertion opening is opened, and which receives and holds the personal digital assistance connected to the connection connector in a state in which at least a part of the apparatus insertion opening is opened; and an adjusting mechanism having a manipulation portion, and adjusting a pivot position of the cover by a manipulation carried out for the manipulation portion.

Therefore, in the electronic apparatus described above, the cover can be pivoted between the closing position where the apparatus insertion opening is closed and the opening position where the apparatus insertion opening is opened. Also, the pivot position of the cover is adjusted by the adjusting mechanism.

The connection unit according to the embodiment of the present disclosure includes the connector unit having the connection connector to which the connector portion of the personal digital assistance is connected, the apparatus insertion opening into which the personal digital assistance is inserted, the cover which is pivoted between the closing position where the apparatus insertion opening is closed and the opening position where the apparatus insertion opening is opened, and which receives and holds the personal digital assistance connected to the connection connector in the state in which at least a part of the apparatus insertion opening is opened, and the adjusting mechanism having the manipulation portion, and adjusting the pivot position of the cover by the manipulation carried out for the manipulation portion.

Therefore, the attachment need not be prepared so as to correspond to the shape and size of the personal digital assistance adapted to be mounted to the connection unit. In addition, in the state in which the personal digital assistance is detached from the connection unit, the apparatus insertion opening is closed by the cover, thereby preventing the grit and dust from being adhered to the connection connector. Therefore, the connection connector can be protected without rocketing the manufacturing cost.

Secondly, the connection unit is provided with the biasing spring for biasing the cover toward the closing position when the cover is pivoted from the intermediate pivot position between the closing position and the opening position to the closing position side with the intermediate pivot position as the reference, and biasing the cover toward the opening position when the cover is pivoted from the intermediate pivot position to the opening position side.

Therefore, the cover is reliably pivoted either toward the closing position or toward the opening position, and the pivot of the cover is prevented from being stopped between the closing position and the opening position. As a result, it is possible to enhance the reliability of the operation of the cover.

Thirdly, the adjusting mechanism is provided with the slider against which the cover is pressed by the biasing spring between the intermediate pivot position and the opening position, and the cover is pivoted between the intermediate pivot position and the opening position by the movement of the slider.

Therefore, with respect to the pivot position of the cover, the adjustment in and after the second time is not required. As a result, it is possible to enhance the usability.

Fourthly, the adjusting mechanism is provided with the feed screw for moving the slider.

Therefore, the adjustment of the pivot position of the cover is simple. As a result, it is possible to enhance the easiness and the speeding-up of the adjustment work.

Fifthly, the rotating dial is used as the manipulation portion of the adjusting mechanism.

Therefore, the adjustment of the pivot position of the cover is simple. As a result, it is possible to further enhance the easiness and the speeding-up of the adjustment work.

Sixthly, the apparatus insertion opening is formed in the chassis, and the cover is inserted into the inside of the chassis as the cover is pivoted from the closing position toward the opening position.

Therefore, in the phase of mounting the personal digital assistance to the connection unit, the cover is prevented from interfering with the personal digital assistance. As a result, the personal digital assistance can be properly mounted to the connection unit.

Seventhly, the cushion is stuck to the portion of the cover which contacts the personal digital assistance.

Therefore, the cover and the personal digital assistance can be prevented from being damaged.

Eighthly, the connection unit is provided with the supporting portion for supporting the connector unit, and the connector unit can be pivoted for the supporting portion in the same direction as the pivot direction of the cover.

Therefore, the load applied to both of the connector portion of the personal digital assistance, and the connection connector of the connection unit when the personal digital assistance is moved is suppressed irrespective of the pivoting operation of the cover. As a result, the connector portion and the connection connector can be prevented from being broken.

Ninthly, the connector unit is made pivotable with the predetermined reference position as the reference, and the connection unit is provided with the returning spring for biasing the connector unit toward the reference portion.

Therefore, a user can usually attach or detach the personal digital assistance to or from the connection unit in the same direction. As a result, it is possible to enhance the usability.

The electronic apparatus according to another embodiment of the present disclosure includes the connection unit to which the personal digital assistance is mounted, in which the connection unit includes: the connector unit having the connection connector to which the connector portion of the personal digital assistance is connected; the apparatus insertion opening into which the personal digital assistance is inserted; the cover which is pivoted between the closing position where the apparatus insertion opening is closed and the opening position where the apparatus insertion opening is opened, and which receives and holds the personal digital assistance connected to the connection connector in the state in which at least the part of the apparatus insertion opening is opened; and the adjusting mechanism having the manipulation portion, and adjusting the pivot position of the cover by the manipulation carried out for the manipulation portion.

Therefore, the attachment need not be prepared so as to correspond to the shape and size of the personal digital assistance adapted to be mounted to the connection unit. In addition, in the state in which the personal digital assistance is detached from the connection unit, the apparatus insertion opening is closed by the cover, thereby preventing the grit and dust from being adhered to the connection connector. Therefore, the connection connector can be protected without rocketing the manufacturing cost.

### BRIEF DESCRIPTION OF THE DRAWINGS

FIG. 1 is a perspective view showing an external appearance of an electronic apparatus according to a first embodiment of the present disclosure;

FIG. 2 is a perspective view showing the electronic apparatus of the first embodiment shown in FIG. 1 together with a personal digital assistance;

FIG. 3 is an exploded perspective view showing the electronic apparatus of the first embodiment shown in FIG. 1;

FIG. 4 is an enlarged cross sectional view showing a construction of a part of the electronic apparatus of the first embodiment shown in FIG. 1;

FIG. 5 is an exploded perspective view showing a construction of a part of the electronic apparatus of the first embodiment shown in FIG. 1;

FIG. 6 is an enlarged perspective view showing a construction of a part of an inner panel;

FIG. 7 is an enlarged perspective view showing a construction of a part of an outer panel;

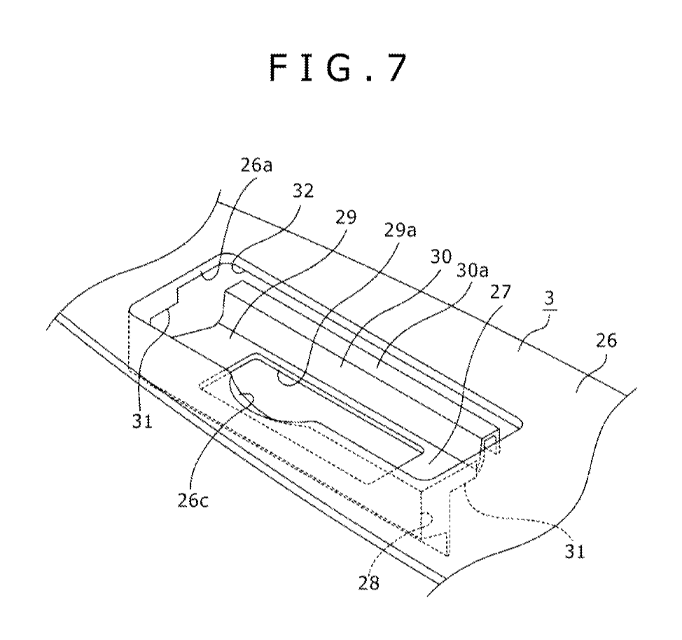

FIG. 8 is an enlarged perspective view showing a state in which a cover is held in a closing position;

FIG. 9 is an enlarged perspective view showing a state in which a cover is held in an opening position;

FIG. 10 is an enlarged cross sectional view showing the state in which the cover is held in the opening position;

FIG. 11 is an enlarged cross sectional view showing a state in which the cover is held in an intermediate pivot position;

FIG. 12 is an enlarged cross sectional view showing a state in which the personal digital assistance is mounted to a connection unit;

FIG. 13 is an enlarged cross sectional view showing a state in which a pivot position of the cover is adjusted by an adjusting mechanism;

FIG. 14 is an enlarged cross sectional view showing a state in which the personal digital assistance is moved irrespective of a pivoting operation of the cover;

FIG. 15 is an enlarged cross sectional view showing a state in which a thin personal digital assistance is mounted to the connection unit;

FIG. 16 is an enlarged cross sectional view showing a state in which when the thin personal digital assistance is mounted to the connection unit, the pivot position of the cover is adjusted by the adjusting mechanism; and

FIG. 17 is an enlarged cross sectional view showing a state in which when the thin personal digital assistance is mounted to the connection unit, the thin personal digital assistance is moved irrespective of the pivoting operation of the cover.

### DETAILED DESCRIPTION OF THE PREFERRED EMBODIMENTS

Embodiments of the present disclosure will be described in detail hereinafter with reference to the accompanying drawings.

In first and second embodiments of the present disclosure which will be described below in detail, an electronic apparatus and a connection unit of the present disclosure are applied to an active speaker and a connection unit included therein, respectively. In this case, a Digital Music Player (DMP) is mounted as a personal digital assistance to the active speaker as the electronic apparatus. Also, the active speaker outputs a sound based on an audio signal recorded in the DMP.

However, the scope of application of the present disclosure is by no means limited to the electronic apparatus for outputting the sound based on the audio signal recorded in the DMP, and the connection unit included therein. That is to say, the present disclosure is generally applied to various kinds of connection units having connection connectors to which various kinds of personal digital assistance such as a mobile phone having a connector portion are connected, respectively, and various kinds of electronic apparatus including the various kinds of connection units.

In the following description, a direction to which a sound outputting portion (speaker portion) of the active speaker (electronic apparatus) is directed is defined as a forward direction. Under this condition, vertical, front-back, and horizontal directions are indicated.

It is noted that the vertical, front-back, and horizontal directions which will be indicated below are indicated for convenience of the description and thus the present disclosure is by no means applied to these directions in a limited way.

### [Construction of Electronic Apparatus]

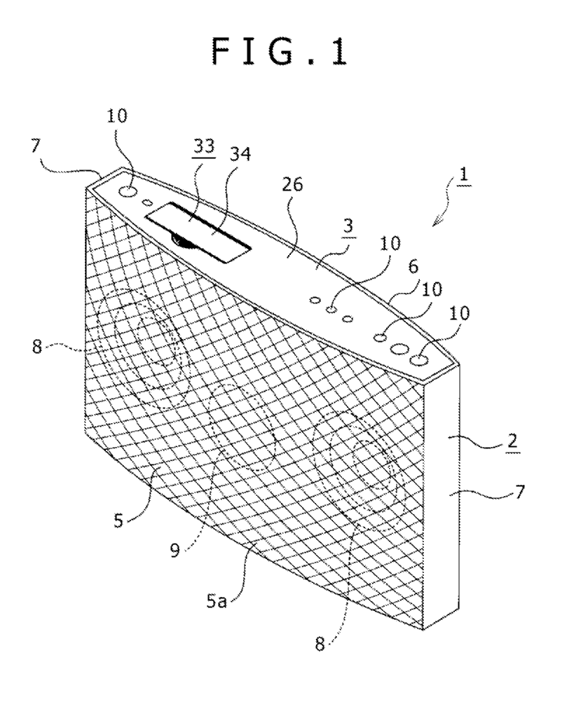

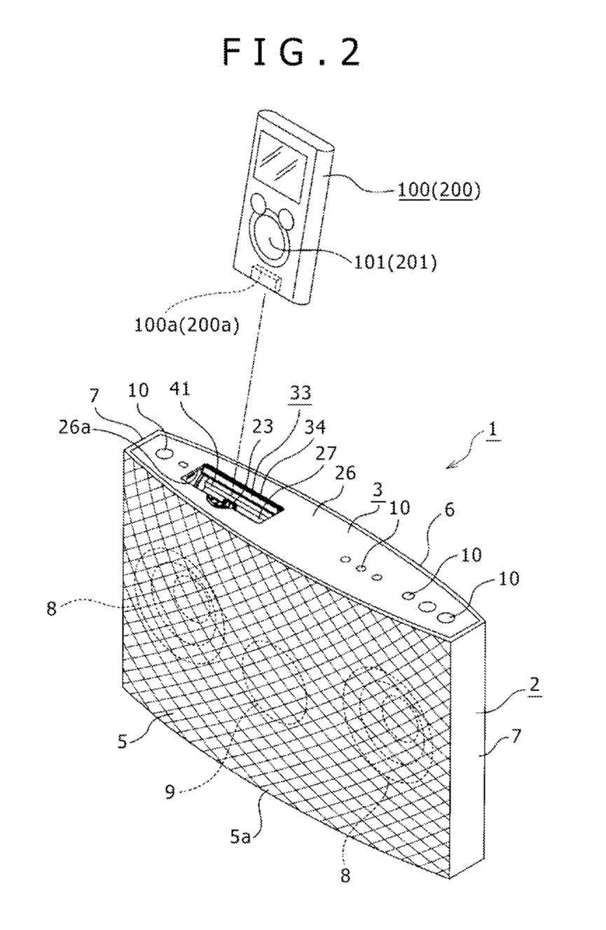

The electronic apparatus (active speaker) 1 includes a chassis 2, and an outer panel 3 (refer to FIGS. 1 to 3).

The chassis 2 is formed in a horizontally long shape by an upper surface portion 4, a front surface portion 5, a rear surface portion 6, side surface portions 7, and a bottom surface portion (not shown). For example, each of the upper surface portion 4 and the bottom surface portion is formed in a boat-like shape. Thus, a front-back width at the center of each of the upper surface portion 4 and the bottom surface portion in the horizontal direction is made maximum.

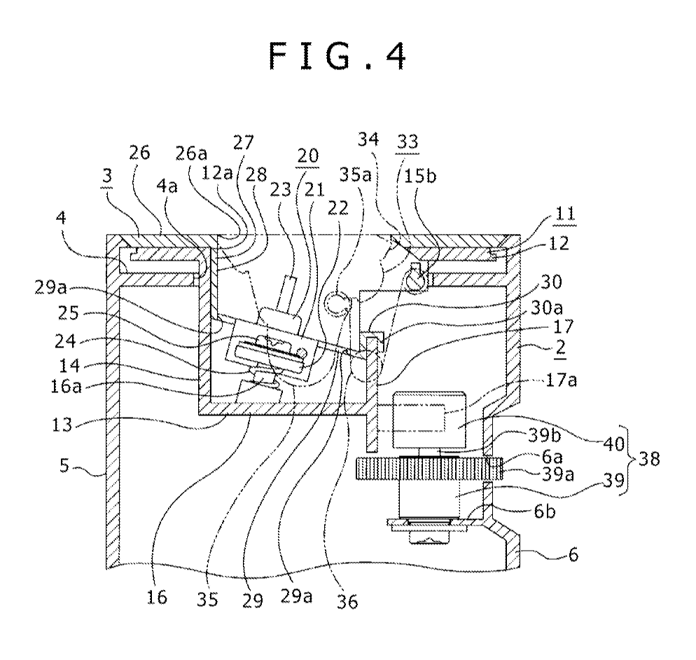

A grill net 5a is formed on the front surface portion 5. A manipulation portion disposition hole 6a is formed in the rear surface portion 6, and a mounting protrusion portion 6b protruding forward is provided on a lower side of the manipulation portion disposition hole 6a (refer to FIG. 4).

First sound outputting portions (speaker portions) 8, 8 are disposed on the right and left sides of the inside of the chassis 2, respectively, separately from each other (refer to FIGS. 1 to 3). A sound path (not shown) becoming a path along which the sound is passed is formed inside the chassis 2. Also, a second sound outputting portion 9 referred to as “a bass reflex” leading to the sound path is disposed between the first sound outputting portions 8, 8. The second sound outputting portion 9 has a function of increasing the level of a bass tone.

A circuit board (not shown) is disposed inside the chassis 2, and an amplifying circuit functioning as an amplifier is formed on the circuit board.

A communication hole 4a is formed in the upper surface portion 4 of the chassis 2.

An electronic substrate (not shown) is disposed on an upper surface of the upper surface portion 4 in the chassis 2. An insertion hole is formed in the electronic substrate so as to completely extend vertically through the electronic substrate. In this case, the insertion hole is formed so as to have the same size and shape as those of the communication hole 4a in the upper surface portion 4. Plural manipulation buttons 10, 10, . . . and a light emitting portion (not shown) are disposed on the upper surface of the electronic substrate.

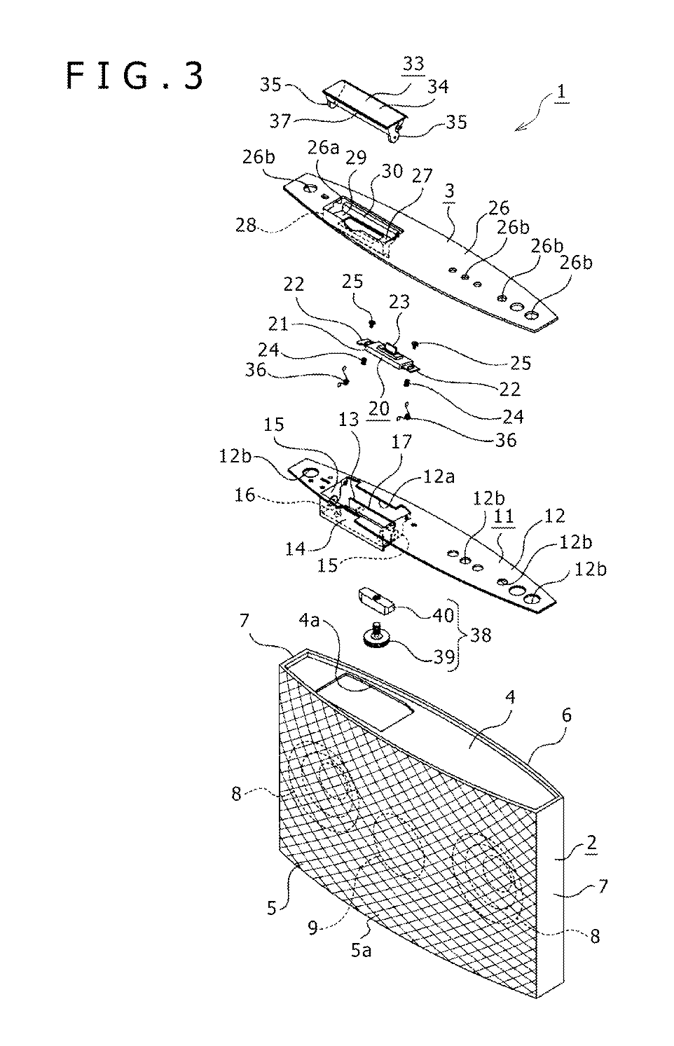

An inner panel 11 is disposed on the upper side of the electrostatic substrate. The inner panel 11 is composed of a plate-like panel portion 12 directed vertically, and a disposition portion 13 located on the lower side of the panel portion 12 (refer to FIGS. 3 to 5).

The panel portion 12 is formed so as to have a size and a shape which are approximately the same as those of the upper surface portion 4 of the chassis 2. Also, the panel portion 12 has an approximately rectangular opening 12a communicating with the disposition portion 13, and manipulation insertion holes 12b, 12b, . . . which are formed on the right and left sides of the opening 12a.

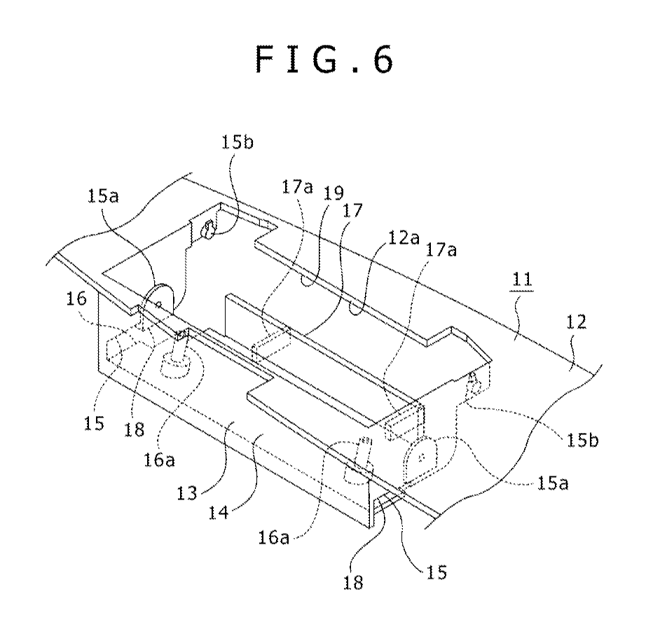

The disposition portion 13 includes a front surface portion 14, side surface portions 15, 15, a bottom surface portion 16, and a rear surface portion 17. In this case, the side surface portions 15, 15 are formed continuously in the right and left side edges of the front surface portion 14, respectively. The bottom surface portion 16 protrudes backward from the lower edge of the front surface portion 14. Also, the rear surface portion 17 protrudes upward from the rear edge of the bottom surface portion 16 (refer to FIG. 6).

The side surface portions 15, 15 are provided with supporting surface portions 15a, 15a on inner surface sides thereof, respectively. Spring supporting protrusion portions 15b, 15b are provided in upper end portions in rear end portions of the inner surfaces of the side surface portions 15, 15, respectively.

Axis-like supporting portions 16a, 16a protruding upward are provided in the bottom surface portion 16 so as to be horizontally separated from each other. Each of the axis-like supporting portions 16a, 16a is formed in a state in which it, for example, is inclined backward at 15° to the vertical direction.

Guide protrusion portions 17a, 17a protruding backward are provided in the rear surface portion 17 so as to be horizontally separated from each other.

In the disposition portion 13, first spaces 18, 18 are formed between the side surface portions 15, 15 and the bottom surface portion 16, and a second space 19 is formed between the upper edge of the rear surface portion 17, and the panel portion 12.

A connector unit 20 is pivotably supported by the supporting portions 16a, 16a which are provided in the bottom surface portion 16 of the disposition portion 13 (refer to FIGS. 3 to 5). The connector unit 20 is composed of a connector case 21, supported protrusion portions 22, 22 protruding horizontally from the connector case 21, a board (not shown) disposed inside the connector case 21, and a connection connector 23 provided on the board. The connection connector 23 protrudes upward from the connector case 21 except for a lower end portion thereof. Supported holes 22a, 22a extending in a front-back direction are formed in the supported protrusion portions 22, 22, respectively.

In a state in which returning springs 24, 24 as compression coil springs are supported by the supporting portions 16a, 16a, respectively, the supporting portions 16a, 16a are inserted into supported holes 22a, 22a of the supported protrusion portions 22, 22, respectively. Also, screw members 25, 25 are screwed into the supporting portions 16a, 16a, whereby the connector unit 20 is supported by the supporting portions 16a, 16a.

Since each of the supported holes 22a, 22a is formed in a shape extending in the front-back direction, the connector unit 20 is made pivotable in the approximately front-back direction with respect to the supporting portions 16a, 16a. Further, the connector unit 20 is biased upward by the returning springs 24, 24.

In a state in which the inner panel 11 is disposed on the upper side of the electronic substrate, the disposition portion 13 is inserted from the upper side into the communication hole 4a of the upper surface portion 4. Also, the manipulation buttons 10, 10, . . . disposed on the electronic substrate are inserted through the manipulation insertion holes 12b, 12b, . . . of the inner panel 11, respectively.

The outer panel 3 is composed of a plate-like decorative board portion 26 directed vertically, and an insertion portion 27 located on the lower side of the plate-like decorative board portion 26.

The plate-like decorative board portion 26 is formed so as to have a size and a shape which are approximately the same as those of the inner panel 11. Also, the decorative board portion 26 includes an approximately rectangular apparatus insertion opening 26a, and manipulation portion disposition holes 26b, 26b, . . . which are formed on the right and left sides of the apparatus insertion opening 26a. In this case, the apparatus insertion opening 26a communicates with the insertion portion 27. A concave-like manipulating concave portion 26c is formed in the decorative board portion 26 so as to be continuous in a front side opening edge of the apparatus insertion opening 26a.

The insertion portion 27 includes a front wall portion 28, a bottom wall portion 29, and a rear wall portion 30. In this case, the bottom wall portion 29 protrudes backward from a lower edge of the front wall portion 28. Also, the rear wall portion 30 protrudes upward from a rear edge of the bottom wall portion 29.

A horizontally long connector insertion hole 29a which completely extends vertically through the bottom wall portion 29 is formed in the bottom wall portion 29.

A coupling portion 30a which is folded so as to be opened downward is provided in an upper end portion of the rear wall portion 30.

In the insertion portion 27, first gaps 31, 31 are formed between a right side edge of the bottom wall portion 29 and the decorative board portion 26, and between a left side edge of the bottom wall portion 29 and the decorative board portion 26, respectively. Also, a second gap 32 is formed between an upper edge of the rear wall portion 30, and the decorative board portion 26.

The outer panel 3 is disposed on an upper side of the inner panel 11 so as to be mounted to the chassis 2. In a state in which the outer panel 3 is disposed on the upper side of the inner panel 11, the insertion portion 27 is inserted from the upper side into the disposition portion 13. Also, the manipulation buttons 10, 10, . . . which are disposed in the electronic substrate so as to be inserted through the manipulation insertion holes 12b, 12b, . . . of the inner panel are inserted into the manipulation portion disposition holes 26a, 26a, . . . to be disposed, respectively.

The rear surface portion 17 which is provided in the disposition portion 13 of the inner panel 11 is inserted from the lower side into the coupling portion 30a which is provided in the rear wall portion 30 of the insertion portion 27 of the outer panel 3 to be coupled thereto. At this time, the connection connector 23 of the connector unit 20 is inserted from the lower side through the connector insertion hole 29a of the bottom wall portion 29.

A cover 33 is pivotally supported by the supporting surface portions 15a, 15a which are provided on the side surface portions 15, 15 of the inner panel 11, respectively (refer to FIGS. 3 to 5). The cover 33 includes a closing surface portion 34 and arm portions 35, 35. In this case, the closing surface portion 34 is formed in a horizontally long plate-like shape. Also, the arm portions 35, 35 protrude approximately downward from the right and left end portions of the closing surface portion 34, respectively.

Spring hanging protrusion portions 35a, 35a are provided in outer surfaces of the arm portions 35, 35, respectively.

A cushion 37 made of a rubber or the like is stuck to a front end portion in the closing surface portion 34 of the cover 33.

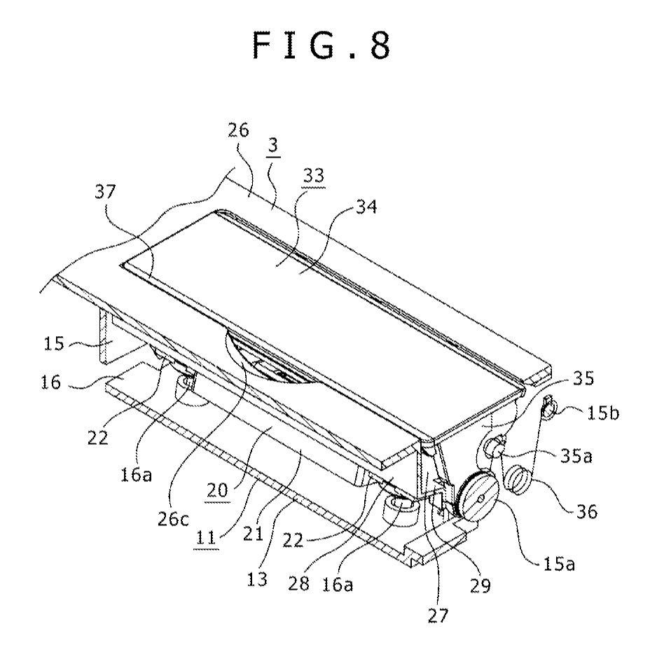

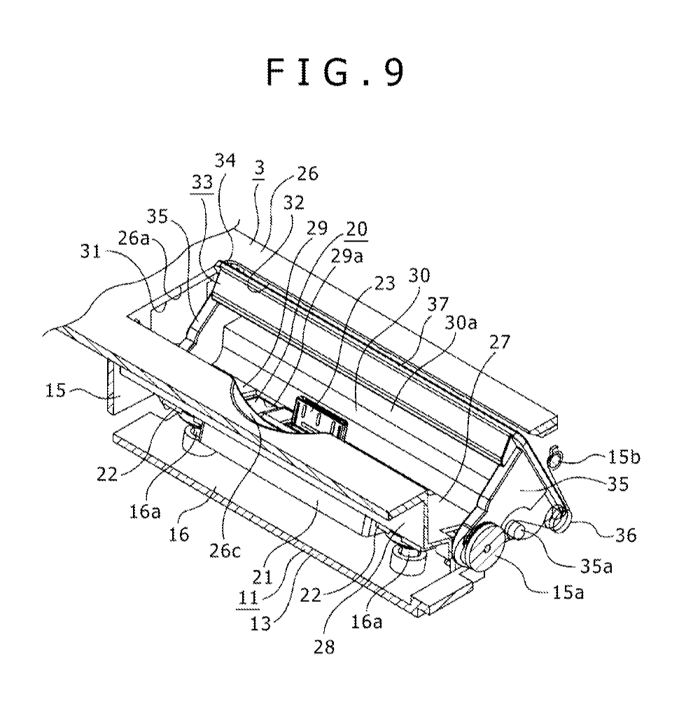

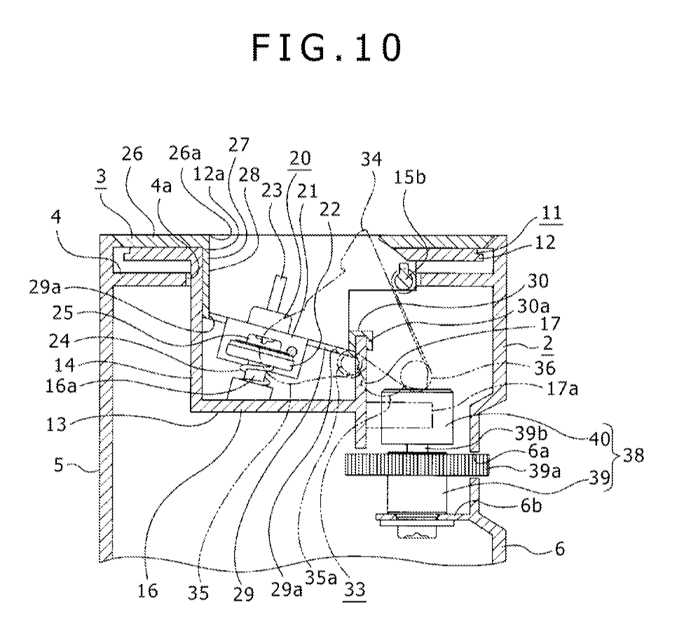

In the cover 33, lower end portions of the arm portions 35, 35 are supported by the supporting surface portions 15a, 15a, respectively. Thus, the cover 33 can be pivoted with respect to the outer panel 3 and the inner panel 11 between a closing position where the apparatus insertion opening 26a of the outer panel 3 is closed (refer to FIGS. 4 and 8), and an opening position where the apparatus insertion opening 26a of the outer panel 3 is opened (refer to FIGS. 9 and 10).

When the cover 33 is pivoted, the closing surface portion 34 is passed through the second space 19 and the second gap 32, and the arm portions 35, 35 are passed through the first space 18, and the first gaps 31, 31, respectively.

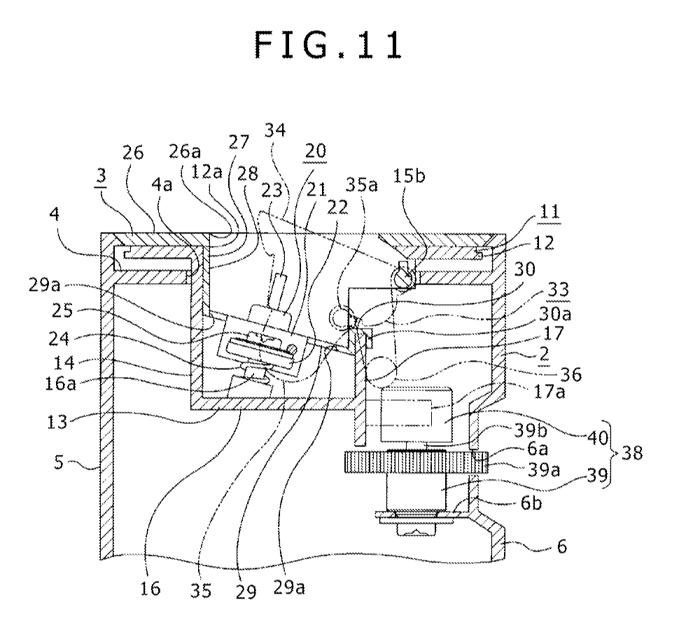

Biasing springs 36, 36 as toggle springs are supported between the spring supporting protrusion portions 15b, 15b of the inner panel 11, and the spring hanging protrusion portions 35a, 35a of the cover 33, respectively. Therefore, when the cover 33 is pivoted from a predetermined intermediate pivot position between the closing position and the opening position (refer to FIG. 11) to the closing position side with the intermediate pivot position as a reference, the cover 33 is biased toward the closing position by the biasing springs 36, 36. On the other hand, when the cover 33 is pivoted from the predetermined intermediate pivot position to the opening position side, the cover 33 is biased toward the opening position by the biasing springs 36, 36.

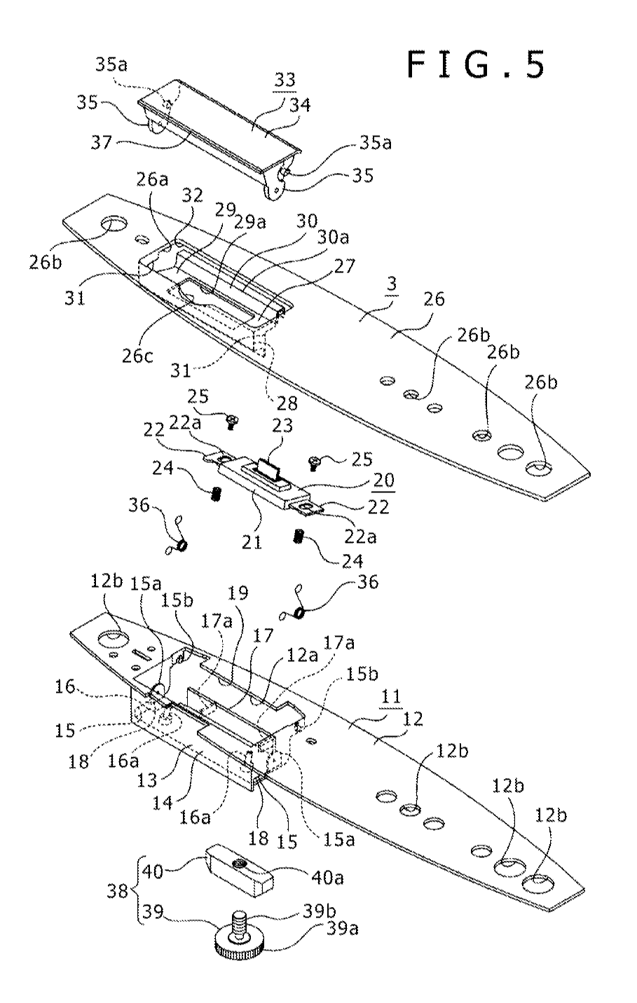

The pivot position of the cover 33 from the intermediate pivot position to the opening position can be adjusted by an adjusting mechanism 38. The adjusting mechanism 38 includes a manipulation body 39 and a slider 40 which is vertically moved by manipulating the manipulation body 39 (refer to FIGS. 4 and 5).

The manipulation body 39 is mounted to a mounting protrusion portion 6b which is provided in the rear surface portion 6 of the chassis 2 in a rotatable state by the screwing or the like. The manipulation body 39 includes a rotating dial 39a and a feed screw 39b protruding upward from the central portion of the rotating dial 39a. A part of the rotating dial 39a is disposed in the manipulation portion disposition hole 6a formed in the rear surface portion 6 of the chassis 2, and a rear end position thereof protrudes backward from the rear surface portion 6. Therefore, the user can rotation-manipulate a part of the rotating dial 39a protruding backward from the outer surface side of the chassis 2.

The slider 40 is formed in a horizontally long block-like shape and includes a screw hole 40a completely extending vertically through the slider 40. The feed screw 39b is screwed into the screw hole 40a of the slider 40 to be located between the guide protrusion portions 17a, 17a on the rear surface side of the rear surface portion 17 of the inner panel 11. Therefore, when the rotating dial 39a is rotation-manipulated to rotate the feed screw 39b, the slider 40 is guided by the guide protrusion portions 17a, 17a in accordance with the rotation direction of the rotating dial 39a to be vertically moved.

The rear edge of the closing surface portion 34 of the cover 33 is pressed against the slider 40 between the intermediate pivot position and the opening position by the biasing forces of the biasing springs 36, 36. Thus, the pivot position of the cover 33 is adjusted by the vertical movement of the slider 40.

The electronic apparatus 1 is constructed in the manner as described above. Also, a connection unit 41 including the connector unit 20, the cover 33, and the adjusting mechanism 38 is constructed. In this case, the connector unit 20 includes the connection connector 23. The cover 33 serves to open and close the apparatus insertion opening 26a. Also, the adjusting mechanism 38 serves to adjust the pivot position of the cover 33.

### [Operation in Electronic Apparatus]

Hereinafter, an operation in the electronic apparatus 1 will be described.

In the state in which the cover 33 is held in the closing position, the cover 33 is biased toward the closing position by the biasing springs 36, 36. Thus, the cushion 37 stuck to the front end portion of the closing surface portion 34 is set in a state in which the cushion 37 contacts the front side opening edge of the apparatus insertion opening 26a of the cover 33 (refer to FIGS. 4 and 8).

Therefore, the connector unit 20 is closed by the cover 33 to protect the connection connector 23, thereby preventing the grit and dust from being adhered to the connection connector 23.

In the state in which the cover 33 is held in the closing position, the connection connector 23 is inclined backward at 15° to the vertical direction in accordance with the direction of each of the supporting portions 16a, 16a which are provided in the bottom surface portion 16 of the inner panel 11.

In the state in which the cover 33 is held in the closing position, the user inserts his/her finger into the manipulating concave portion 26c which is formed in the decorative board portion 26 of the outer panel 3 to address his/her finger to the front end portion of the closing surface portion 34. Also, the closing surface portion 34 is depressed backward, so that the cover 33 is pivoted toward the opening position. At this time, when the slider 40 is located in the lower side movement end, the cover 33 is pivoted at the largest angle to reach the opening position.

The rear end portion of the closing surface portion 34 contacts the upper surface of the slider 40 thereby holding the cover 33 in the opening position. Thus, the closing surface portion 34 of the cover 33 is pressed against the slider 40 by the biasing force of the biasing springs 36, 36 (refer to FIGS. 9 and 10). The cover 33 is pivoted to the opening position, whereby the apparatus insertion opening 26a is most largely opened.

When the cover 33 is going to be pivoted from the closing position toward the opening position, the cover 33 is moved to the lower side of the apparatus insertion opening 26a to be inserted into the inside of the chassis 2. In a state in which the cover 33 is moved to the opening position, the front end portion of the closing surface portion 34 is located just front side of the rear edge of the apparatus insertion opening 26a. Also, only the front end portion of the closing surface portion 34 of the cover 33 is protruded slightly upward from the decorative board portion 26 of the outer panel 3.

Next, the personal digital assistance 100 is connected to the connection connector 23 of the connector unit 20. The personal digital assistance 100, for example, is formed in a thin in the front-back direction and vertically long shape, and a lower end portion thereof is provided with a female connector portion 100a. A part of a front surface of the personal digital assistance 100 is formed as a manipulation surface 101.

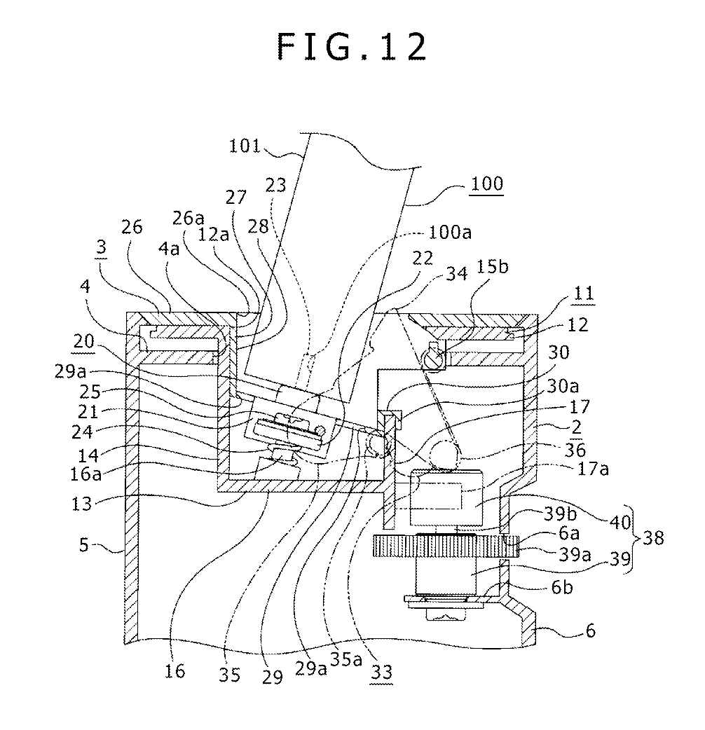

The personal digital assistance 100 is inserted from the apparatus insertion opening 26a of the outer panel 3 into the insertion portion 27, and the connector portion 100a is connected to the connection connector 23, whereby the personal digital assistance 100 is mounted to the connection unit 41 (refer to FIG. 12). At this time, along with the inclined angle of the connection connector 23, the personal digital assistance 100, for example, is inclined backward at an angle of 15°.

In the phase of mounting the personal digital assistance 100 to the connection unit 41, the approximately entire cover 33 is inserted into the inside of the chassis 2. Therefore, in the phase of mounting the personal digital assistance 100 to the connection unit 41, the cover 33 is prevented from interfering with the personal digital assistance 100, and the personal digital assistance 100 can be suitably mounted to the connection unit 41.

In a state in which the cover 33 is held in the opening position and the personal digital assistance 100 is mounted to the connection unit 41, the front end of the closing surface portion 34 of the cover 33 is located backward and separately from a back surface of the personal digital assistance 100.

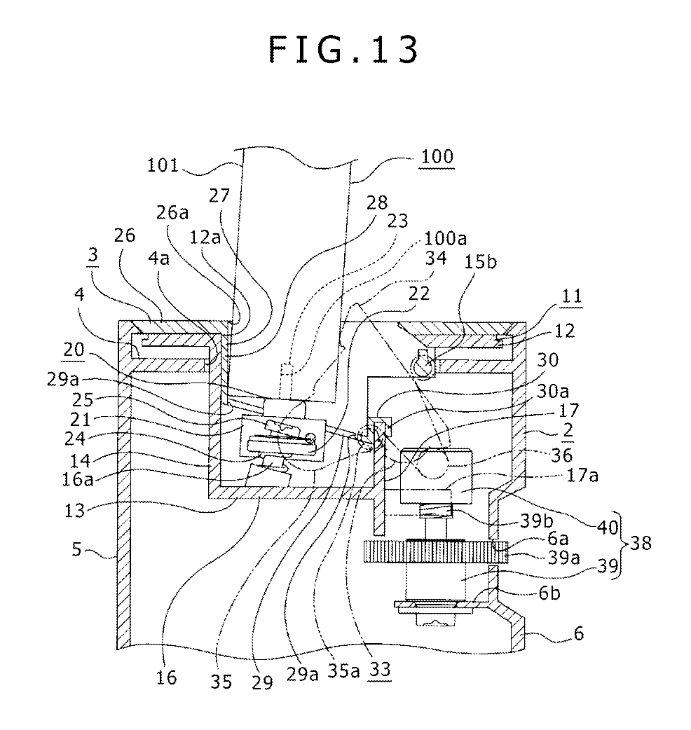

Subsequently, when the rotating dial 39a of the manipulation body 39 is manipulated, so that the slider 40 is moved upward, the closing surface portion 34 is pressed up by the slider 40 and thus the cover 33 is pivoted toward the closing position against the biasing forces of the biasing springs 36, 36 (refer to FIG. 13). Therefore, the personal digital assistance 100 is depressed forward by the closing surface portion 34 and thus is pivoted integrally with the connector unit 20 with respect to the supporting portions 16a, 16a.

At this time, since the cushion 37 stuck to the front end portion of the closing surface portion 34 of the cover 33 contacts the rear surface of the personal digital assistance 100, the cover 33 and the personal digital assistance 100 can be prevented from being damaged.

The user suitably rotates the rotating dial 39a, thereby making it possible to hold the personal digital assistance 100 at a desired angle.

At this time, the cover 33 is located between the intermediate pivot position and the opening position. Thus, the cover 33 is biased toward the opening position by the biasing springs 36, 36, and the rear end portion of the closing surface portion 34 is pressed against the upper surface of the slider 40. Therefore, even when the vibration or the like is generated, the cover 33 is prevented from being pivoted toward the closing position by the vibration. As a result, the cover 33 is held in a stable state.

When the user manipulates the manipulation surface 101 from the front side of the personal digital assistance 100, the backward load is applied to the personal digital assistance 100. However, since the personal digital assistance 100 is pressed by the cover 33 to be held, the personal digital assistance 100 is not moved backward by the manipulation made for the manipulation surface 101, and thus it is possible to ensure the satisfactory operability.

In addition, the personal digital assistance 100 is held by the cover 33. Therefore, in the phase of the manipulation made for the manipulation surface 101, the load is prevented from being applied to each of the connector portion 100a of the personal digital assistance 100, and the connection connector 23 of the connection unit 41.

It is noted that as described above, the connector unit 20 can be pivoted approximately in the front-back direction with respect to the supporting portions 16a, 16a, and thus is pivoted along with the movement of the personal digital assistance 100 irrespective of the pivoting operation of the cover 33.

Therefore, the load is prevented from being applied to each of the connector portion 100a of the personal digital assistance 100, and the connection connector 23 of the connection unit 41 when the personal digital assistance 100 is moved approximately front-back direction irrespective of the pivoting operation of the cover 33. As a result, the connector portion 100a and the connection connector 23 can be prevented from being broken.

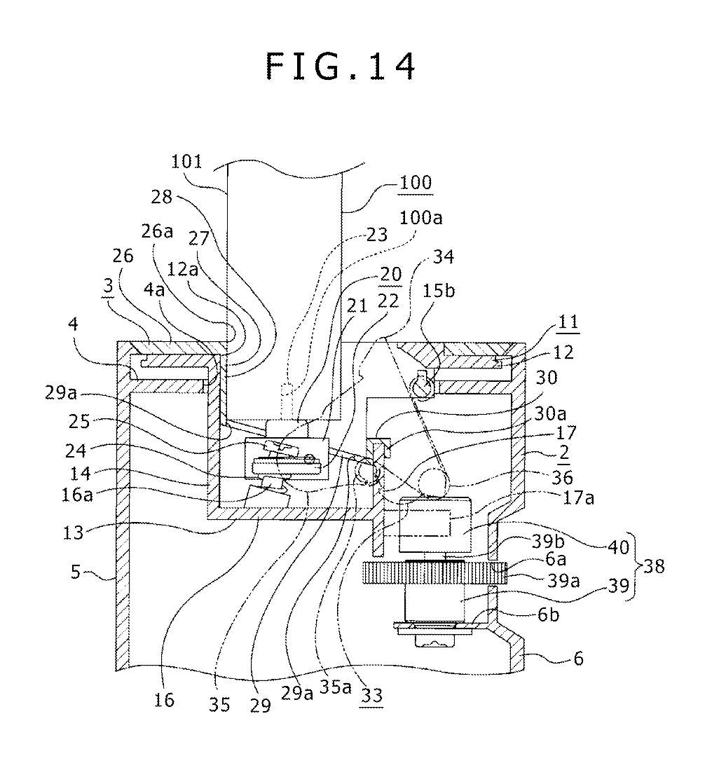

In addition, when the personal digital assistance 100 is moved approximately forward irrespective of the pivoting operation of the cover 33, the connector unit 20 can be pivoted to a position where the front surface of the personal digital assistance 100 contacts the front side opening edge of the apparatus insertion opening 26a (refer to FIG. 14). Thus, when the personal digital assistance 100 is largely moved forward, the connector portion 100a and the connection connector 23 can be prevented from being broken.

On the other hand, when the personal digital assistance 100 is moved approximately backward irrespective of the pivoting operation of the cover 33, the connector unit 20 can be pivoted to a position where the rear surface of the personal digital assistance 100 contacts the front end portion of the closing surface portion 34. Thus, even when the personal digital assistance 100 is moved backward, the connector portion 100a and the connection connector 23 can be prevented from being broken.

Note that, when the personal digital assistance 100 is moved approximately in the front-back direction irrespective of the pivoting operation of the cover 33, the connector unit 20 is pivoted with each of the supporting portions 16a, 16a as a fulcrum point along with the movement of the personal digital assistance 100. In this case, however, when the force applied to the personal digital assistance 100 approximately in the front-back direction is released, the connector unit 20 is returned together with the personal digital assistance 100 back to the original position (reference position) by the biasing forces of the returning springs 24, 24.

Therefore, the user can usually attach or detach the personal digital assistance 100 to or from the connection unit 41 in the same direction. As a result, it is possible to enhance the usability of the electronic apparatus 1.

The personal digital assistance 100 can be detached from the connection unit 41 in such a way that the personal digital assistance 100 is moved approximately upward while the personal digital assistance 100 is grasped, thereby releasing the connection of the connector portion 100a to the connection connector 23.

In a state in which the personal digital assistance 100 is detached from the connection unit 41, the cover 33 is pivoted to the closing portion. As a result, the connector unit 20 is closed by the cover 33 to protect the connection connector 23, thereby preventing the grit and dust from being adhered to the connection connector 23.

In a state in which the cover 33 is held in the closing position, the cover 33 is biased toward the closing position by the biasing springs 36, 36. Thus, there is obtained a state in which the cushion 37 stuck to the front end portion of the closing surface portion 34 contacts the front side opening edge of the apparatus insertion opening 26a of the cover 33.

In the state in which the cover 33 is held in the closing position in such a manner, the cover 33 is biased toward the closing position by the biasing springs 36, 36. Therefore, even when the vibration or the like is generated, the cover 33 is prevented from being pivoted toward the closing position by the vibration. As a result, the cover 33 is held in the stable state in the closing position.

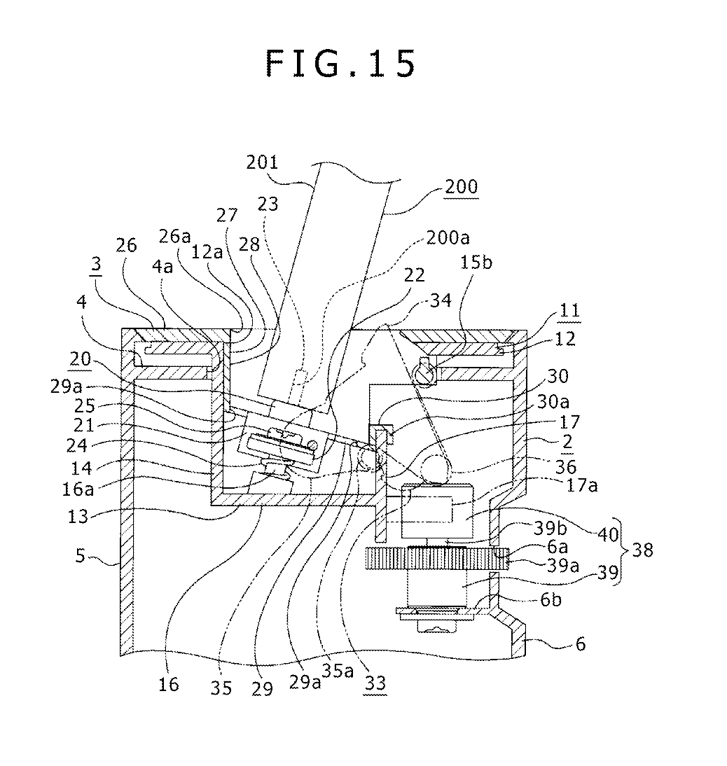

In the electronic apparatus 1, a personal digital assistance which is different in thickness from the personal digital assistance 100 can be connected to the connection unit 41. That is to say, a personal digital assistance which is thicker than the personal digital assistance 100 can be connected to the connection unit 41. Also, a personal digital assistance 200 which is thinner than the personal digital assistance 100 can also be connected to the connection unit 41 (refer to FIGS. 15 to 17).

The lower end portion of the personal digital assistance 200 is provided with a female connector portion 200a. A part of a front surface of the personal digital assistance 200 is formed as a manipulation surface 201.

The personal digital assistance 200 is inserted from the apparatus insertion opening 26a of the outer panel 3 into the insertion portion 27, and the connector portion 200a is connected to the connection connector 23, whereby the personal digital assistance 200 is mounted to the connection unit 41 (refer to FIG. 15). At this time, along with the inclined angle of the connection connector 23, the personal digital assistance 200, for example, is inclined backward at an angle of 15°.

In the state in which the cover 33 is held in the opening position and thus the personal digital assistance 200 is mounted to the connection unit 41, the front end of the closing surface portion 34 of the cover 33 is located backward from the rear surface of the personal digital assistance 200 in spaced relation to thereto.

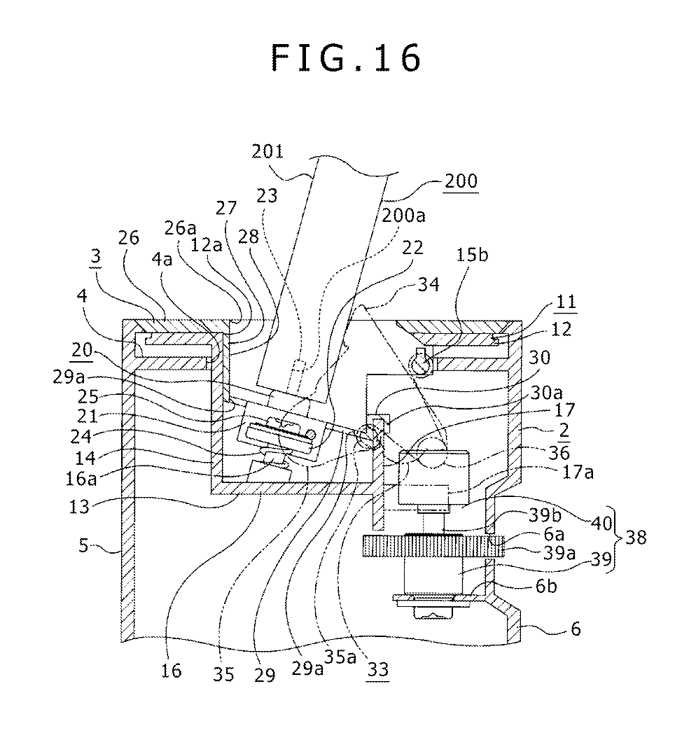

Subsequently, when the rotating dial 39a of the manipulation body 39 is manipulated, so that the slider 40 is moved upward, the closing surface portion 34 is pressed up by the slider 40 and thus the cover 33 is pivoted toward the closing position against the biasing forces of the biasing springs 36, 36 (refer to FIG. 16). Therefore, the personal digital assistance 200 is depressed forward by the closing surface portion 34 and thus is pivoted integrally with the connector unit 20 with respect to the supporting portions 16a, 16a.

At this time, since the cushion 37 stuck to the front end portion of the closing surface portion 34 of the cover 33 contacts the rear surface of the personal digital assistance 200, the cover 33 and the personal digital assistance 200 can be prevented from being damaged.

The user suitably rotates the rotating dial 39a, thereby making it possible to hold the personal digital assistance 200 at a desired angle.

When the user manipulates a manipulation surface 201 from the front side of the personal digital assistance 200, a backward load is applied to the personal digital assistance 200. However, since the personal digital assistance 200 is pressed by the cover 33 to be held, the personal digital assistance 200 is not moved backward by the manipulation made for the manipulation surface 201, and thus it is possible to ensure the satisfactory operability.

In addition, the personal digital assistance 200 is held by the cover 33. Therefore, in the phase of the manipulation made for the manipulation surface 201, the load is prevented from being applied to each of the connector portion 200a of the personal digital assistance 200, and the connection connector 23 of the connection unit 41.

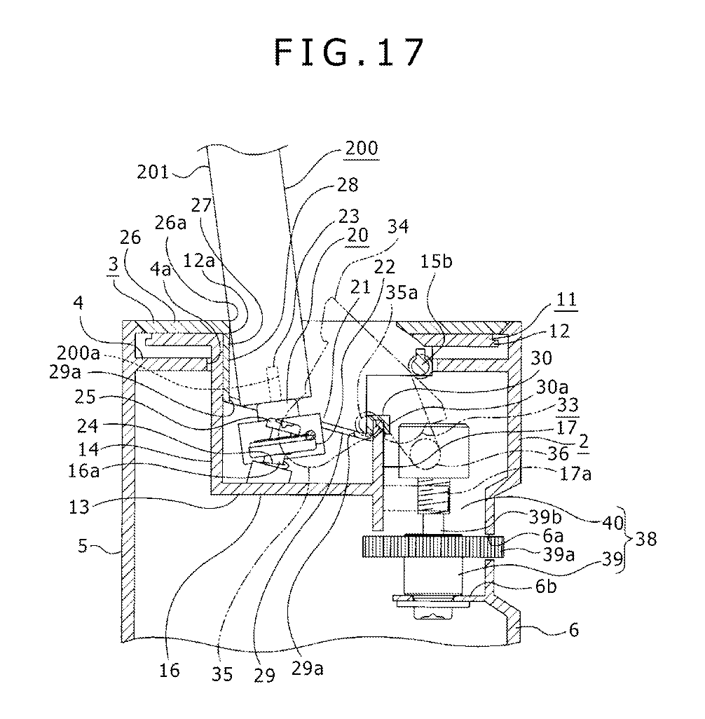

In addition, when the personal digital assistance 200 is moved approximately forward irrespective of the pivoting operation of the cover 33, the connector unit 20 can be pivoted to a position where the front surface of the personal digital assistance 200 contacts the front side opening edge of the apparatus insertion opening 26a (refer to FIG. 17). Thus, even when the personal digital assistance 200 is largely moved forward, the connector portion 200a and the connection connector 23 can be prevented from being broken.

In addition, when the personal digital assistance 200 is moved approximately backward irrespective of the pivoting operation of the cover 33, the connector unit 20 can be pivoted to a position where the front surface of the personal digital assistance 200 contacts the front end portion of the cover 33. Thus, even when the personal digital assistance 200 is moved approximately backward, the connector portion 200a and the connection connector 23 can be prevented from being broken.

On the other hand, when the personal digital assistance 200 is moved approximately backward irrespective of the pivoting operation of the cover 33, the connector unit 20 can be pivoted to a position where the rear surface of the personal digital assistance 200 contacts the front end portion of the closing surface portion 34 of the cover 33. Thus, even when the personal digital assistance 200 is moved approximately backward, the connector portion 200a and the connection connector 23 can be prevented from being broken.

It is noted that when a personal digital assistance which is thicker than the personal digital assistance 100 is mounted to the connection unit 41, the connector portion may be connected to the connection connector 23 in such a way that the connector unit 20 is pivoted slightly forward. The personal digital assistance is mounted to the connection unit 41 in such a manner, whereby the rear surface of the personal digital assistance, and the closing surface portion 34 of the cover 33 can be prevented from contacting each other, thereby avoiding the damage of both of the rear surface of the personal digital assistance, and the closing surface portion 34 of the cover 33.

The personal digital assistance 200 can be detached from the connection unit 41 in such a way that the personal digital assistance 200 is moved approximately upward while the personal digital assistance 200 is grasped, thereby releasing the connection of the connector portion 200a to the connection connector 23.

In a state in which the personal digital assistance 200 is detached from the connection unit 41, the cover 33 is pivoted to the closing portion. As a result, the connector unit 20 is closed by the cover 33 to protect the connection connector 23, thereby preventing the grit and dust from being adhered to the connection connector 23.

In a state in which the cover 33 is held in the closing position, the cover 33 is biased toward the closing position by the biasing springs 36, 36. Thus, there is obtained a state in which the cushion 37 stuck to the front end portion of the closing surface portion 34 contacts the front side opening edge of the apparatus insertion opening 26a of the cover 33.

### [Connection Unit]

The connection unit 41 according to a second embodiment of a second embodiment of the present disclosure, as described above, includes the connector unit 20, the apparatus insertion opening 26a, the cover 33, and the adjusting mechanism 38. In this case, the connector unit 20 has the connection connector 23, and the connector portion 100a of the personal digital assistance 100 is connected to the connector unit 20. The personal digital assistance 100 is inserted into the apparatus insertion opening 26a. The cover 33 is pivoted between the closing position where the apparatus insertion opening 26a is closed and the opening position where the apparatus insertion opening 26a is opened, and receives and holds the personal digital assistance 100 connected to the connection connector 23 in the state in which at least the part of the apparatus insertion opening 26a is opened. Also, the adjusting mechanism 38 has the manipulation portion (the rotating dial 39a), and adjusts the pivot position of the cover 33 by the manipulation carried out for the manipulation portion (the rotating dial 39a).

It is noted that the personal digital assistance 200 or the like, for example, may also be used instead of using the personal digital assistance 100.

### [Conclusions]

As has been described so far, in the electronic apparatus 1, the cover 33 for opening and closing the apparatus insertion opening 26a of the outer panel 3 is provided, and the pivot position of the cover 33 can be adjusted by the adjusting mechanism 38.

Therefore, the attachment need not be prepared so as to correspond to the shape and size of the personal digital assistance 100, 200 or the like adapted to be mounted to the connection unit 41. In addition, in the state in which the personal digital assistance 100, 200 or the like is detached from the connection unit 41, the apparatus insertion opening 26a is closed by the cover 33, thereby preventing the grit and dust from being adhered to the connection connector 23. Therefore, the connection connector 23 can be protected without rocketing the manufacturing cost.

In addition, when the cover 33 is pivoted from the intermediate pivot position to the closing position side with the intermediate pivot position as the reference, the cover 33 is biased toward the closing position by the biasing springs 36, 36. On the other hand, when the cover 33 is pivoted from the intermediate pivot position to the opening position side, the cover 33 is biased toward the opening position by the biasing springs 36, 36.

Therefore, the cover 33 is reliably pivoted either toward the closing position or toward the opening position, and the pivot of the cover 33 is prevented from being stopped between the closing position and the opening position. As a result, it is possible to enhance the reliability of the operation of the cover 33.

In addition, the rear edge of the closing surface portion 34 of the cover 33 is pressed against the slider 40 between the intermediate pivot position and the opening position by the biasing springs 36, 36. Thus, the pivot position of the cover 33 is adjusted by the adjusting mechanism 38. As a result, when the cover 33 is pivoted to the opening position side after the cover 33 has been temporarily pivoted to the closing position side, the cover 33 is usually held in the last-minute pivot position.

Therefore, with respect to the pivot position of the cover 33, the adjustment in and after the second time adjustment is not required. As a result, it is possible to enhance the usability of the electronic apparatus 1.

Furthermore, the adjusting mechanism 38 is provided with the feed screw 39b for moving the slider 40. Thus, the slider 40 is moved by the feed screw 39b, thereby adjusting the pivot position of the cover 33. Therefore, the adjustment of the pivot position of the cover 33 is simple. As a result, it is possible to enhance the easiness and the speeding-up of the adjustment work.

In addition, since the slider 40 is moved by the feed screw 39b, the slider 40 is moved and held in the position corresponding to the pivot position of the feed screw 39b. As a result, the slider 40 is not unnecessarily moved and thus the cover 33 can be reliably held in the adjusted pivot position.

Furthermore, since the rotating dial 39a is used as the manipulation portion for the adjusting mechanism 38, the adjustment for the pivot position of the cover 33 is simple. Thus, it is possible to further enhance the easiness and speeding-up of the adjustment work.

### [Others]

In the foregoing, there is shown the case where in the state before the personal digital assistance 100, 200 or the like is mounted to the connection unit 41, the connection connector 23 is inclined backward at 15° to the vertical direction. However, the angle at which the connection connector 23 is inclined before the personal digital assistance 100, 200 or the like is mounted to the connection unit 41 is by no means limited to 15°, and thus can be set an arbitrary angle.

### [Technique of the Present Disclosure]

The technique of the present disclosure can adopt the following constitutions.

(1) A connection unit including: a connector unit having a connection connector to which a connector portion of a personal digital assistance is connected; an apparatus insertion opening into which the personal digital assistance is inserted; a cover which is pivoted between a closing position where the apparatus insertion opening is closed and an opening position where the apparatus insertion opening is opened, and which receives and holds the personal digital assistance connected to the connection connector in a state in which at least a part of the apparatus insertion opening is opened; and an adjusting mechanism having a manipulation portion, and adjusting a pivot position of the cover by a manipulation carried out for the manipulation portion.

(2) The connection unit described in the paragraph (1), further including a biasing spring biasing the cover toward the closing position when the cover is pivoted from an intermediate pivot position between the closing position and the opening position to the closing position side with the intermediate pivot position as a reference, and biasing the cover toward the opening position when the cover is pivoted from the intermediate pivot position to the opening position side.

(3) The connection unit described in the paragraph (2), in which the adjusting mechanism is provided with a slider against which the cover is pressed by the biasing spring between the intermediate pivot position and the opening position, and the cover is pivoted between the intermediate pivot position and the opening position by a movement of the slider.

(4) The connection unit described in the paragraph (3), in which the adjusting mechanism is provided with a feed screw moving the slider.

(5) The connection unit described in any one of the paragraphs (1) to (4), in which a rotating dial is used as the manipulation portion of the adjusting mechanism.

(6) The connection unit described in any one of the paragraphs (1) to (5), in which the apparatus insertion opening is formed in a chassis; and the cover is inserted into an inside of the chassis as the cover is pivoted from the closing position toward the opening position.

(7) The connection unit described in any one of the paragraphs (1) to (6), in which a cushion is stuck to a portion of the cover which contacts the personal digital assistance.

(8) The connection unit described in any one of the paragraphs (1) to (7), in which the connection unit is provided with a supporting portion supporting the connector unit; and the connector unit is made pivotable for the supporting portion in the same direction as the pivot direction of the cover.

(9) The connection unit described in the paragraph

(8), in which the connector unit is made pivotable with a predetermined surface position as a reference, in which the connection unit is provided with a returning spring biasing the connector unit toward the reference position.

(10) An electronic apparatus including: a connection unit to which a personal digital assistance is mounted, in which the connection unit includes: a connector unit having a connection connector to which a connector portion of the personal digital assistance is connected; an apparatus insertion opening into which the personal digital assistance is inserted; a cover which is pivoted between a closing position where the apparatus insertion opening is closed and an opening position where the apparatus insertion opening is opened, and which receives and holds the personal digital assistance connected to the connection connector in a state in which at least a part of the apparatus insertion opening is opened; and an adjusting mechanism having a manipulation portion, and adjusting a pivot position of the cover by a manipulation carried out for the manipulation portion.

The concrete shapes and constructions shown in the embodiments described above are each merely an example for the concretion when the present disclosure is embodied, and thus the technical scope of the present disclosure is not intended to be construed in a limiting sense by the concrete shapes and constructions shown in the embodiments described above.

The present disclosure contains subject matter related to that disclosed in Japanese Priority Patent Application JP 2011-279503 filed in the Japan Patent Office on Dec. 21, 2011, the entire content of which is hereby incorporated by reference.

What is claimed is:

1. A connection unit, comprising:
a connector unit having a connection connector to which a connector portion of a personal digital assistance is connected;
an apparatus insertion opening into which said personal digital assistance is inserted;
a cover which is pivoted between a closing position where said apparatus insertion opening is closed and an opening position where said apparatus insertion opening is opened, and which receives and holds said personal digital assistance connected to said connection connector in a state in which at least a part of said apparatus insertion opening is opened; and
an adjusting mechanism having a manipulation portion, and adjusting a pivot position of said cover by a manipulation carried out for said manipulation portion.

2. The connection unit according to claim 1, further comprising
a biasing spring biasing said cover toward the closing position when said cover is pivoted from an intermediate pivot position between the closing position and the opening position to the closing position side with the intermediate pivot position as a reference, and biasing said cover toward the opening position when said cover is pivoted from the intermediate pivot position to the opening position side.

3. The connection unit according to claim 2, wherein
said adjusting mechanism is provided with a slider against which the cover is pressed by said biasing spring between the intermediate pivot position and the opening position, and
said cover is pivoted between the intermediate pivot position and the opening position by a movement of said slider.

4. The connection unit according to claim 3, wherein said adjusting mechanism is provided with a feed screw moving said slider.

5. The connection unit according to claim 1, wherein a rotating dial is used as said manipulation portion of said adjusting mechanism.

6. The connection unit according to claim 1, wherein
said apparatus insertion opening is formed in a chassis, and
said cover is inserted into an inside of said chassis as said cover is pivoted from the closing position toward the opening position.

7. The connection unit according to claim 1, wherein a cushion is stuck to a portion of said cover which contacts said personal digital assistance.

8. The connection unit according to claim 1, further comprising
a supporting portion supporting said connector unit,
wherein said connector unit is made pivotable for said supporting portion in the same direction as the pivot direction of said cover.

9. The connection unit according to claim 8, wherein
said connector unit is made pivotable with a predetermined surface position as a reference, and
said connection unit is further provided with a returning spring biasing said connector unit toward said reference position.

10. An electronic apparatus, comprising:
a connection unit to which a personal digital assistance is mounted,
wherein said connection unit includes
a connector unit having a connection connector to which a connector portion of the personal digital assistance is connected,
an apparatus insertion opening into which said personal digital assistance is inserted,
a cover which is pivoted between a closing position where said apparatus insertion opening is closed and an opening position where said apparatus insertion opening is opened, and which receives and holds said personal digital assistance connected to said connection connector in a state in which at least a part of said apparatus insertion opening is opened, and
an adjusting mechanism having a manipulation portion, and adjusting a pivot position of said cover by a manipulation carried out for said manipulation portion.
